(19) United States
(12) Patent Application Publication
(10) Pub. No.: US 2011/0102926 A1
(43) Pub. Date: May 5, 2011

(54) MIRROR AND PROCESS FOR OBTAINING A MIRROR

(75) Inventors: Fabrice Abbott, Vienne (FR); Bruno Cordier, Quincy-Voisins (FR); Bernard Nghiem, Arsy (FR); Olivier Selles, Paris (FR)

(73) Assignee: Saint-Gobain Glass France, Courbevoie (FR)

(21) Appl. No.: 13/002,402

(22) PCT Filed: Jul. 2, 2009
(86) PCT No.: PCT/FR2009/051291

§ 371 Date: Jan. 3, 2011

(30) Foreign Application Priority Data
Jul. 3, 2008 (FR) 0854539

(51) Int. Cl. G02B 5/08; B05D 5/06; C23C 14/34; C23C 14/35

(52) U.S. Cl. 359/883; 427/162; 427/569; 204/192.27

(57) ABSTRACT

The subject of the invention is a mirror, especially a front-face mirror and/or a mirror for concentrating solar energy, comprising a material, which mirror comprises a substrate coated with a multilayer comprising at least one silver layer and at least one protective layer located on top of said at least one silver layer, at least one protective layer being characterized in that at least one of its physicochemical characteristics varies with the distance from the substrate.

The invention relates to the field of mirrors, of the type comprising at least one silver layer.

Silver layers deposited on substrates, especially glass substrates, are useful in many respects, in particular for their properties of reflecting electromagnetic radiation in the infrared and/or visible ranges. Relatively thick silver layers completely reflect visible light and are widely employed in the production of mirrors.

The main drawback of silver is its propensity to be oxidized and to be corroded on contact with air and/or water, this corrosion being catalyzed in the presence of atmospheric pollutants such as sulfides or chlorides.

The silver layers of mirrors are therefore always coated with protective layers or with protective varnishes, and are even preferably placed so that the protective layers or varnishes are not in direct contact with atmospheric pollutants. In the case of mirrors, the silver layers are generally coated with an opaque protective varnish (an organic lacquer) located on the rear face of the mirror. These conventional mirrors are called “rear-face mirrors” or “face 2 mirrors”.

In certain applications, it may however be advantageous to have mirror coatings located on the front face, also called face 1.

This is for example the case of mirrors used for concentrating solar energy, the reflection properties of which must be maximized. However, in the case of a rear-face mirror the light rays pass twice through the glass thickness (once before reflection and once after reflection). This attenuates the reflected energy and necessitates the use of particularly expensive glasses, the light transmission of which is maximized thanks to a very low content of iron oxides. The same type of problem arises for example in the case of mirrors for telescopes or mirrors for optics (especially mirrors for laser cavities).

It is therefore useful to have silver-protecting layers that are transparent, resistant to chemical attack, abrasion resistant and scratch resistant and that provide long-term protection of the silver layer.

Patent application WO 2007/089387 discloses silica protective layers deposited by a sol-gel process, especially for applications in the field of face 1 mirrors for concentrating solar energy.

U.S. Pat. No. 4,780,372 discloses vacuum-deposited silicon nitride layers.

These layers, indicated as being very dense, contribute to retarding the diffusion, through the protective layer, of species (gases, water, chlorides, sulfides, etc.) that contribute to silver corrosion.

The aim of the invention is to further improve the protection of silver layers, by proposing protective layers capable of protecting silver from corrosion over a very long time.

For this purpose, one subject of the invention is a mirror comprising a material which comprises a substrate coated with a multilayer comprising at least one silver layer and at least one protective layer located on top of said at least one silver layer, at least one protective layer being characterized in that at least one of its physicochemical characteristics varies with the distance from the substrate.

When the multilayer comprises several protective layers, it is advantageous for all the protective layers, or at least that one located on top of the silver layer further from the substrate, to have at least one of their physicochemical characteristics varying with the distance from the substrate.

It was apparent to the inventors that the corrosion protection properties could be further improved by having at least one protective layer that was not uniform through its thickness.

Without wishing to be tied to any one scientific theory, it would seem that obtaining a layer as dense as possible is not, contrary to what was believed hitherto, the best solution for preventing or impeding any diffusion of corrosive polluting species into the silver layer. High densities are often accompanied by high mechanical stresses within the layer, which may cause cracks to appear, these being preferential paths for the diffusion of polluting species. It was apparent to the inventors that a layer varying in density through the thickness would be less liable to generate this type of defect and would consequently be more effective in terms of protecting the silver from corrosion than a layer of the same thickness having the same or higher average density, but uniformly dense. The reason for this is that a succession of regions of different density interrupt the propagation of cracks. The diffusion paths, and consequently the diffusion times, are thus considerably lengthened. The same applies for properties other than density, as will be explained in the rest of the text.

A layer is defined as being an extent of a substance whose thickness is small compared with its surface extent. A layer is characterized in particular by the absence of major discontinuities in terms of chemical composition of said substance. A major discontinuity in terms of chemical composition may in particular be an abrupt change in the nature of the atoms making up the layer affecting more than 30%, especially more than 10%, of said atoms. Thus, the protective layer according to the invention cannot be understood to be a multilayer consisting of layers differing fundamentally in chemical nature. Nevertheless, small discontinuities may exist, for example because of variations in stoichiometry or variations in amounts of dopants or impurities, as will be explained in the rest of the text. Alternatively, the protective layer may have the same chemical composition at all points.

At least one, and preferably the or each, protective layer is preferably transparent to radiation in the solar spectrum range (visible and near infrared).

At least one, and preferably the or each, protective layer is preferably chosen from oxides, nitrides and oxynitrides. In particular, at least one, and preferably the or each, protective layer is preferably an oxide, nitride or oxynitride of an element chosen from: Si, Al, Zr, Ti, Hf, Bi and Ta. They may especially be layers such as SiO₂, Al₂O₃, ZrO₂, TiO₂, Si₃N₄, AlN, SiON, Bi₂O₃ or Ta₂O₅ layers (without making any presumptions regarding the precise stoichiometry of the layers), or any one of their mixtures. These layers are in fact transparent, abrasion resistant and resistant to chemical attack. Silicon nitride (Si₃N₄) is preferred for its very high chemical resistance. Oxynitrides are particularly appreciated for their high chemical resistance and their high transparency. All these materials constituting the protective layer may be hydrogenated (for example silicon nitride).

The at least one physicochemical characteristic that varies with the distance from the substrate is preferably chosen from one or more of the following characteristics: the density; the stoichiometry; the degree of crystallization; the nature of the crystalline phase; and the content of impurities or dopants. The property that varies with the distance from the substrate may be a purely physical property, such as the density. In this case, the chemical composition may be the same at all points.

One preferred embodiment consists of a protective layer having the same chemical composition (preferably based on Si₂N₄ or SiO₂) at all points, the density of said layer varying continuously (and preferably periodically) with the distance from the substrate.

In the case of a variation in stoichiometry, at least one barrier layer may for example be of the MO_{X} or MN_{Y} or MO_{X}N_{Y} type, M being a metal chosen from Si, Al, Zr, Ti, Hf, Bi and Ta and the values of x and y varying with the distance from the substrate. This variation is preferably continuous, but it may also have small discontinuities, for example discontinuities that modify the x and/or y values by less than 0.05 or even less than 0.01. As a preferred example, mention may be made of a layer of SiOₓN_{y} composition in which the x and y values vary continuously with the distance from the substrate. This variation may in particular be linear or periodic. Cracks thus see the structure of the layer changing during their possible advance, which helps to retard their propagation.

Likewise, the presence of dopants or impurities, the content of which varies with the thickness, will impede crack propagation within the layer. The term “defect” or “impurity” is understood to mean any minor element in terms of weight, present in particular in an amount of less than 5%, or even 2% and indeed even 1% or less by weight, for example metal ions or organic species coming from the decomposition of organometallic precursors used for depositing the protective layer, as will be explained later.

It is preferable for at least one physicochemical characteristic, especially the density, to vary continuously, in other words to vary as a continuous function of the distance from the substrate. This is because abrupt changes or discontinuities in properties run the risk of creating interfaces between several regions of the layer, in this case a lower region in which the property takes a given value and an upper region in which this value is very different. As a result, mechanical problems (for example delamination between these two regions) or optical problems (for example the creation of interference) may arise.

This continuous variation is preferably periodic. In the case of the density for example, it is preferable for the layer to have a variation in density that alternates with the distance from the substrate between high-density regions and low-density regions, for example regions in which the density is at least 10%, or even 20% and even 30% greater than the average density of the layer, and zones in which the density is at least 10%, or even 20% and even 30% lower than the average density of the layer. The number of regions is preferably equal to or greater than 4, especially 6, or even 8 or indeed even 10. The presence of these less dense and softer regions enables the stresses in the denser regions to be relaxed, thus preventing the formation of defects.

At least one, and especially the or each, protective layer is preferably obtained by plasma-enhanced chemical vapor deposition or PECVD. This deposition technique under reduced pressure involves the decomposition of precursors under the effect of a plasma, in particular under the effect of the collisions between the excited or ionized species of the plasma and the molecules of the precursor. The plasma may for example be obtained by a radiofrequency discharge created between two plane electrodes (the technique is then referred to as RF PECVD) or using electromagnetic waves in the microwave range. In particular, the microwave PECVD technique using coaxial tubes to generate the plasma is particularly advantageous as it allows deposition on a large moving substrate with particularly high deposition rates. The precursors may be inorganic precursors (hydrides, halides, etc.) or organometallic precursors. In the latter case, the protective layer may contain carbon-containing species, such as hydrocarbons, as impurities.

The advantages of the PECVD technique are numerous and include in particular the high deposition rate and the possibility of depositing on surfaces of complex shape. The latter advantage is particularly useful in the case of layers intended to protect silver layers deposited on parabolic or cylindro-parabolic mirrors. The PECVD technique also has the advantage of covering the edges and edge faces of the substrate which are usually the weak point of conventional protection systems. This is because it frequently happens in the case of mirrors that corrosion of the silver starts via the edge faces, before progressively gaining the entire surface of the mirror.

The PECVD technique also makes it possible for a variation, especially a continuous variation, in the physicochemical properties of a layer, for example the density, the stoichiometry or the content of impurities or dopants, to be very easily obtained. The following parameters may in particular be modified during deposition: the pressure in the deposition chamber; the power; or the nature of the precursors. Increasing the pressure in the deposition chamber generally encourages the formation of less-dense layers. It is thus possible for the pressure to be continuously varied during deposition in order to obtain, correlatively, a continuous variation in the density. Likewise, by introducing different precursors during a deposition phase it is possible to obtain a region of slightly different chemical nature within the layer. This may for example involve temporarily introducing precursors of a dopant, within the meaning of this term defined above, this dopant then having a higher content in well-defined regions of the protective layer according to the invention. It may also involve introducing a different precursor of the same element. For example, temporary introduction of an organometallic silicon precursor (the predominant precursor being silane SiH₄) enables carbon-containing impurities to be introduced into certain regions of the protective layer. An increase in the power may result in an increase in the density of the layer.

Other deposition techniques are possible, but are less preferred. Mention may in particular be made of magnetron sputtering, evaporation techniques or even atmospheric-pressure PECVD processes, especially those using dielectric-barrier discharge technology.

The thickness of at least one, and especially the or each, protective layer is preferably equal to or greater than 50 nm, especially 100 nm, or even 200 nm or 300 nm and/or equal to or less than 5 microns, especially 3 microns, or even 2 microns or 1 micron, and even 500 nm. The largest thicknesses will contribute to improving the protection properties of the layer as regards corrosion resistance and also abrasion resistance, to the detriment however of the rate of deposition. A compromise must therefore be found that will depend on the application envisioned (for example, whether or not an outdoor application).

The substrate may in particular be made of flat or curved glass, made of metal or made of a rigid plastic. In the case of a front-face mirror, the substrate is not necessarily transparent, and metals or rigid plastics may be employed. In the case of rear-face mirrors, the substrate is based on glass or possibly made of a transparent polymer, such as polycarbonate (PC) or polymethyl methacrylate (PMMA). In the case of applications for concentrating solar energy, the substrate will generally be curved, preferably with a parabolic, cylindro-parabolic or approximately parabolic shape.

The multilayer may comprise a single silver layer or several, for example two, three or four and even five or more silver layers. In this case, it is possible to have a single protective layer on top of the silver layer furthest from the substrate, or to have several protective layers, including at least one on top of the silver layer furthest from the substrate. The other protective layers may, depending on the case, be placed within the multilayer so as to further increase the protection.

The thickness of at least one, and especially the or each, silver layer is preferably between 50 and 200 nm, especially between 60 and 120 nm. Preferably, a single silver layer is deposited, especially by silver plating processes in which silver salts in solution are chemically reduced. When the substrate is made of glass, it is generally sensitized using an SnCl₂-based solution.

The or at least one protective layer is preferably the last layer of the multilayer, i.e. the outermost layer starting from the substrate, and therefore the layer in contact with the atmosphere.

When a protective layer is based on titanium oxide and constitutes the last layer of the multilayer, the protective layer may also play another role, in this case that of giving the material antisoiling or self-cleaning properties. These properties are accentuated when the titanium oxide is crystallized in anatase form, as described in patent application EP-A-0 850 204.

The mirror according to the invention is preferably a front-face mirror and/or a mirror for concentrating solar energy. It may especially be a mirror used in a structure for concentrating solar energy in which the solar energy is reflected by generally parabolic or cylindro-parabolic mirrors and focused onto a tube through which a heat-transfer fluid circulates. The fluid, being heated up, exchanges its heat with water, the steam formed driving a turbine for generating electricity. The advantage of a front-face mirror for this type of application is that the radiation is reflected by the silver layer without passing through the substrate. It is thus possible to employ substrates made of ordinary, less expensive glass, i.e. glass for which the light transmission is not maximized. It is also possible to employ opaque substrates. The mirror according to the invention may have a parabolic or cylindro-parabolic shape or may be flat (or slightly curved through the effect of mechanical tension) but may form a parabola when assembled with several other, generally four, mirrors. The advantages of the invention in the case of mirrors for concentrating solar energy are numerous: by having no layer located behind the substrate, it is possible to simplify the systems for fastening the mirrors, no longer running the risk of damaging the layers; by having the silver layer as face 1, it is possible to maximize the reflection of energy toward the heat-transfer fluid and therefore to maximize efficiency of power generation. Over a number of years of operation of the generator, the gain in power generated is therefore considerable.

Other applications are particularly advantageous, for example in the optical field: mirrors for telescopes; mirrors for laser cavities, etc.

Another subject of the invention is a process for obtaining a mirror according to the invention, in which process a coating is deposited on a substrate, said coating comprising at least one silver layer and at least one protective layer located on top of said at least one silver layer, at least one protective layer being characterized in that at least one of its physicochemical characteristics varies with the thickness.

Preferably, at least one, and especially the or each, protective layer is deposited by plasma-enhanced chemical vapor deposition, the pressure in the deposition chamber and/or the power and/or the nature of the precursors being modified during the deposition.

Increasing the pressure in the deposition chamber generally encourages the formation of less-dense layers. It is thus possible for the pressure to be continuously varied during deposition in order to obtain, correlatively, a continuous variation in the density. Likewise, by introducing different precursors during a deposition phase it is possible to obtain a region of slightly different chemical nature within the layer. This may for example involve temporarily introducing precursors of a dopant, within the meaning of this term defined above, this dopant then having a higher content in well-defined regions of the protective layer according to the invention. It may also involve introducing a different precursor of the same element. For example, temporary introduction of an organometallic silicon precursor (the predominant precursor being silane SiH₄) enables carbon-containing impurities to be introduced into certain regions of the protective layer. An increase in the power may result in an increase in the density of the layer.

Alternatively, but less preferably, at least one, and especially the or each, protective layer may be deposited by sputtering, especially magnetron sputtering, the pressure in the deposition chamber and/or the power being varied during the deposition.

Increasing the pressure, as in the case of PECVD, promotes the formation of less-dense layers.

When the deposition technique employed allows deposition on a moving substrate, the temporal notions used hitherto must be interpreted as spatial notions. Thus, a temporal deposition phase in the case of a discontinuous (batch) technique corresponds to a spatial region of the deposition device in the case of a continuous technique.

The invention will be better understood on reading the nonlimiting implementation example that follows.

### EXAMPLE

The example is a front-face mirror formed from a glass substrate coated with a silver mirror layer which is itself coated with an Si₃N₄ layer having a density that varies continuously with the distance from the substrate.

A flat substrate of clear glass of the soda-lime-silica type, sold under the brand name SGG Planilux® by the Applicant, was introduced into a reduced-pressure RF PECVD deposition chamber. This glass substrate was coated with a silver layer deposited by a conventionally employed silver plating technique consisting in chemically reducing silver salts in solution. This layer, the thickness of which was 80 nm, reflected practically all visible radiation and therefore could be employed as a mirror.

The technique employed was RF PECVD, i.e. plasma-enhanced chemical vapor deposition in which a plasma was generated using two electrodes.

The protective layer was a layer of hydrogenated silicon nitride SiₓNₓH_{z}. The precursors formed an

SiH₄/NH₃ mixture diluted in an N₂/H₂ mixture. This dilution provided better stabilization of the plasma, while contributing to the physicochemical properties of the layer obtained.

The deposition was carried out in four successive steps. In the first step, the pressure in the chamber was fixed at 400 mTorr, the power deposited by the plasma per unit area being 0.15 W/cm². In the second step, the pressure was progressively increased up to 600 mTorr, the power being 0.10 W/cm². The third and fourth steps were the same as the first and second steps respectively.

The deposition was carried out at a temperature close to the ambient temperature (below 100° C.).

What was thus obtained was a hydrogenated silicon nitride layer 200 nm in thickness that could be roughly subdivided into four regions each corresponding to a deposition step. The first and third regions (starting from the substrate) were regions in which the density of Si₃N₄ was higher than in the second and fourth regions. The protective layer could thus be considered as a superposition of four individual layers of the same chemical composition alternating in density between a high density and a lower density.

The corrosion resistance of the material obtained was remarkable.

1. A mirror comprising a material, wherein the material comprises a substrate coated with a multilayer comprising at least one silver layer and at least one protective layer located on top of said at least one silver layer, wherein the at least one protective layer has at least one physicochemical characteristic which varies with the distance from the substrate.

2. The mirror as claimed in claim 1, wherein the at least one protective layer is selected from the group consisting of an oxide, a nitride and an oxynitride.

3. The mirror as claimed in claim 1, wherein at least one protective layer is an oxide, nitride or oxynitride of an element selected from the group consisting of: Si, Al, Zr, Ti, Hf, Bi and Ta.

4. The mirror as claimed in claim 1, wherein the at least one physicochemical characteristic which varies with the thickness is at least one selected from the following characteristics: density; stoichiometry; degree of crystallization; nature of the crystalline phase; and content of impurities or dopants.

5. The mirror as claimed in claim 1, wherein the at least one physicochemical characteristic varies continuously with the thickness.

6. The mirror as claimed in claim 1, wherein the at least one protective layer is obtained by a process comprising plasma-enhanced chemical vapor deposition.

7. The mirror as claimed in claim 1, wherein the thickness of at least one protective layer is between 50 nm and 5 microns.

8. The mirror as claimed in claim 1, wherein the substrate comprises a flat or curved glass, metal or a rigid plastic.

9. The mirror as claimed in claim 1, wherein the thickness of the at least one silver layer is between 50 and 200 nm.

10. The mirror as claimed in claim 1, wherein at least one protective layer is the last layer of the multilayer.

11. The mirror as claimed in claim 1, which is a front-face mirror and/or a mirror for concentrating solar energy.

12. A process for obtaining a mirror as claimed in claim 1, comprising depositing a coating on a substrate, said coating comprising at least one silver layer and at least one protective layer located on top of said at least one silver layer, and wherein at least one of said at least one protective layer is physicochemical characteristics varies with the thickness.

13. The process as claimed in claim 12, wherein at least one protective layer is deposited by plasma-enhanced chemical vapor deposition, the pressure in the deposition chamber and/or the power and/or the nature of the precursors being modified during the deposition.

14. The process as claimed in claim 12, such that at least one protective layer is deposited by sputtering, the pressure in the deposition chamber and/or the power being varied during the deposition.

15. The process as claimed in claim 14, wherein the at least one protective layer is deposited by magnetron sputtering.
